(19) United States
(12) Patent Application Publication
(10) Pub. No.: US 2025/0219623 A1
(43) Pub. Date: Jul. 3, 2025

(54) Sampling device and clock adjustment circuit thereof

(71) Applicant: REALTEK SEMICONDUCTOR CORPORATION, Hsinchu (TW)

(72) Inventor: WEI-CIAN HONG, Hsinchu (TW)

(21) Appl. No.: 18/985,118

(22) Filed: Dec. 18, 2024

(30) Foreign Application Priority Data
Dec. 28, 2023 (TW) 112151413

(51) Int. Cl. H03K 5/01; H03H 7/06

(52) U.S. Cl. CPC H03K 5/01; H03H 7/06

(57) ABSTRACT

A sampling device includes a clock generation circuit, a clock adjustment circuit, and a sampling circuit. The clock generation circuit is configured to generate a first clock and a second clock according to a reference clock. The clock adjustment circuit is configured to adjust a direct current (DC) level of one of the first clock and the second clock to generate a third clock and a fourth clock. The sampling circuit is configured to sample an input signal according to the third clock and the fourth clock to generate an output signal. The sampling circuit includes a transmission gate. The transmission gate includes a P-channel Metal-Oxide-Semiconductor Field-Effect Transistor (PMOS transistor) and an N-channel Metal-Oxide-Semiconductor Field-Effect Transistor (NMOS transistor) that respectively receive the third clock and the fourth clock.

### BACKGROUND OF THE INVENTION

### 1. Field of the Invention

The present invention generally relates to clocks, and, more particularly, to the adjustment of a sampling clock.

### 2. Description of Related Art

FIG. 1 shows a conventional clock generation circuit and its output clocks. A clock generation circuit 100 converts a single-ended reference clock CLKs into differential-ended clocks CLKp and CLKn. In some applications, the voltage domain of the reference clock CLKs is different from the voltage domain of the clock CLKp and the clock CLKn. For example, the peak-to-peak value of the reference clock CLKs is 0.8 V, while the peak-to-peak values of the clock CLKp and the clock CLKn may be 1 V.

The clock CLKp and the clock CLKn may respectively be used to control a P-channel Metal-Oxide-Semiconductor Field-Effect Transistor (hereinafter referred to as PMOS transistor) and an N-channel Metal-Oxide-Semiconductor Field-Effect Transistor (hereinafter referred to as NMOS transistor) of a transmission gate. However, when the rising edges and falling edges of the clock CLKp and the clock CLKn are not aligned (e.g., the period(s) of the clock CLKp and/or the clock CLKn are/is changed due to process, voltage, and/or temperature variations), the transmission gate faces the issue where the PMOS transistor and the NMOS transistor do not turn on (conduct) or off (not conduct) simultaneously, leading to a degradation in the performance of the circuit utilizing the transmission gate. For example, when the transmission gate is utilized in a sampling circuit, the aforementioned issue leads to a decrease in the linearity of the sampling circuit.

### SUMMARY OF THE INVENTION

In view of the issues of the prior art, an object of the present invention is to provide a sampling device and its clock adjustment circuit, so as to make an improvement to the prior art.

According to one aspect of the present invention, a clock adjustment circuit is provided. The clock adjustment circuit has an input port and an output port and is configured to adjust an input clock pair to generate an output clock pair. The clock adjustment circuit includes a control voltage generation circuit, an alternating current (AC) coupling circuit, a direct current (DC) voltage generation circuit, and a determination circuit. The control voltage generation circuit includes a transistor and a reference resistor and is configured to generate a control voltage according to the reference resistor. The transistor is controlled by the control voltage. The AC coupling circuit is coupled between the input port and the output port. The DC voltage generation circuit is configured to generate a DC voltage. The determination circuit is coupled to the output port, the control voltage generation circuit, and the DC voltage generation circuit, and is configured to couple the control voltage or the DC voltage to the output port according to the output clock pair.

According to another aspect of the present invention, a clock adjustment circuit is provided. The clock adjustment circuit has an input port and an output port and is configured to adjust an input clock pair to generate an output clock pair. The clock adjustment circuit includes a control voltage generation circuit, an AC coupling circuit, an analog-to-digital converter (ADC), a DC voltage generation circuit, and a determination circuit. The control voltage generation circuit includes a transistor and a reference resistor and is configured to generate a control voltage according to the reference resistor. The transistor is controlled by the control voltage. The AC coupling circuit is coupled between the input port and the output port. The ADC is coupled to the control voltage generation circuit and configured to generate an intermediate signal according to the control voltage. The DC voltage generation circuit is configured to generate a DC voltage according to the intermediate signal. The determination circuit is coupled to the output port, the ADC, and the DC voltage generation circuit, and is configured to couple the intermediate signal to the DC voltage generation circuit according to the output clock pair.

According to still another aspect of the present invention, a sampling device is provided. The sampling device includes a clock generation circuit, a clock adjustment circuit, and a sampling circuit. The clock generation circuit is configured to generate a first clock and a second clock according to a reference clock. The clock adjustment circuit is coupled to the clock generation circuit and configured to adjust a DC level of one of the first clock and the second clock to generate a third clock and a fourth clock. The sampling circuit is coupled to the clock adjustment circuit and configured to sample an input signal according to the third clock and the fourth clock to generate an output signal. The sampling circuit includes a transmission gate. The transmission gate includes a PMOS transistor and an NMOS transistor. The PMOS transistor and the NMOS transistor respectively receive the third clock and the fourth clock. The clock adjustment circuit includes a negative feedback circuit. The negative feedback circuit includes a reference resistor and a transistor, and the clock adjustment circuit adjusts the first clock or the second clock according to a resistance value of the reference resistor and an aspect ratio of the transistor. The transistor has a substantially identical aspect ratio to either the PMOS transistor or the NMOS transistor.

The technical means embodied in the embodiments of the present invention can solve at least one of the problems of the prior art. Therefore, compared to the prior art, the present invention can improve the circuit performance compared to the prior art.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a conventional clock generation circuit and its output clocks.

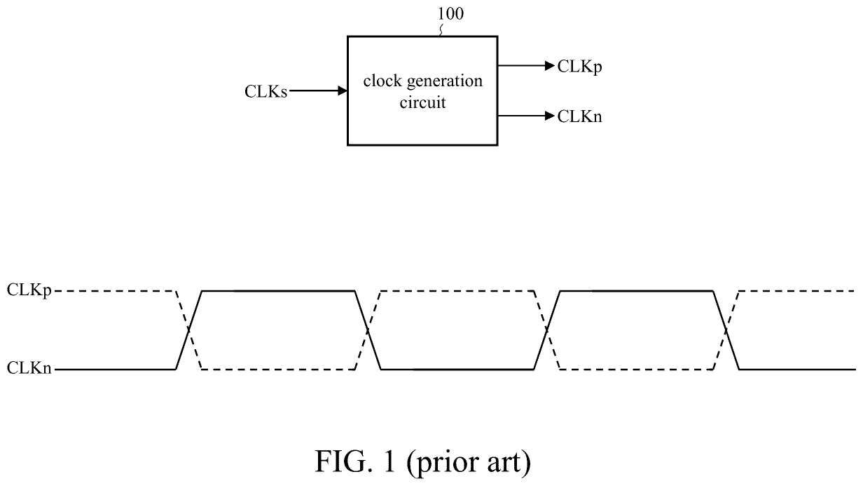

FIG. 2 is a circuit diagram of a clock adjustment circuit according to an embodiment of the present invention.

FIG. 3 is a circuit diagram of a sampling device according to an embodiment of the present invention.

FIG. 4 is a schematic diagram of the waveforms of the clocks, the logic signal, and the filtered logic signal.

FIG. 5 is a circuit diagram of the clock adjustment circuit according to another embodiment of the present invention.

FIG. 6 is a circuit diagram of a direct current (DC) voltage generation circuit according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a sampling device and its clock adjustment circuit. On account of that some or all elements of the sampling device and its clock adjustment circuit could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

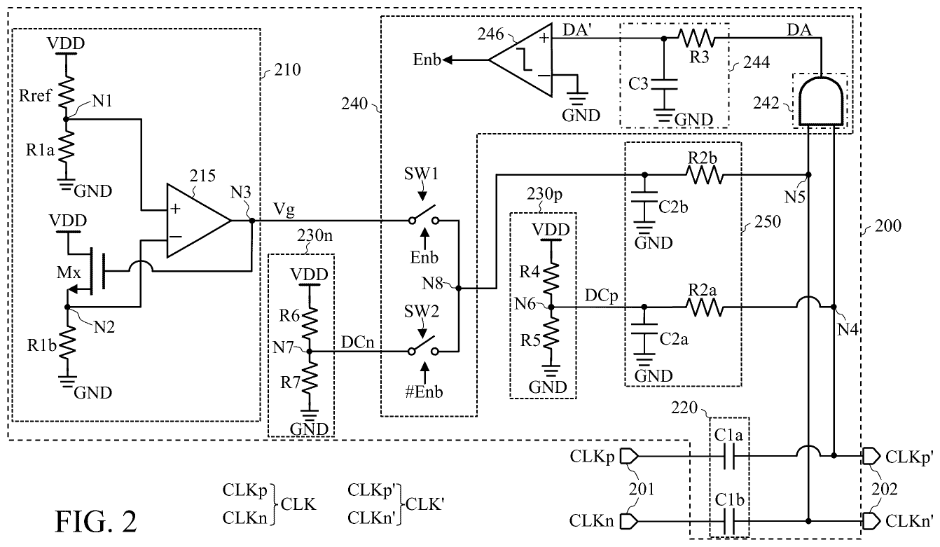

Reference is made to FIG. 2, which is a circuit diagram of a clock adjustment circuit according to an embodiment of the present invention. A clock adjustment circuit 200 receives an input clock pair CLK (including a clock CLKp and a clock CLKn) at an input port 201 and outputs an output clock pair CLK′ (including a clock CLKp′ and a clock CLKn′) at an output port 202. The clock adjustment circuit 200 is configured to adjust the input clock pair CLK to generate the output clock pair CLK′. The clock adjustment circuit 200 includes a control voltage generation circuit 210, an alternating current (AC) coupling circuit 220, a direct current (DC) voltage generation circuit 230n, a DC voltage generation circuit 230p, a determination circuit 240, and a low-pass filter (LPF) circuit 250 that are coupled to each other.

The control voltage generation circuit 210 includes an amplifier 215 (e.g., an operational amplifier (OP), but not limited to this), a reference resistor Rref, a resistor R1a, a resistor R1b, and a transistor Mx. The reference resistor Rref is coupled between the reference voltage VDD and a node N1 (i.e., an input terminal of the amplifier 215). The resistor R1a is coupled between the node N1 and the reference voltage GND. The transistor Mx is coupled between the reference voltage VDD and the node N2 (i.e., an input terminal of the amplifier 215). The resistor R1b is coupled between a node N2 and the reference voltage GND. The gate of the transistor Mx is coupled or electrically connected to a node N3 (i.e., the output terminal of the amplifier 215).

The amplifier 215 outputs (or generates) a control voltage Vg according to the voltage at the node N1 (i.e., according to the reference resistor Rref) and the voltage at the node N2. The gate of the transistor Mx receives the control voltage Vg; as a result, the turn-on resistance of the transistor Mx changes with the control voltage Vg. The control voltage generation circuit 210 is a negative feedback circuit. In other words, when the control voltage generation circuit 210 settles, the voltage at the node N1 is substantially equal to the voltage at the node N2. At this time, if the resistor R1a is equal to the resistor R1b, then the turn-on resistance of the transistor Mx is substantially equal to the resistance value of the reference resistor Rref.

The AC coupling circuit 220 is coupled between the input port 201 and the output port 202 and includes a capacitor C1a and a capacitor C1b. A terminal of the capacitor C1a receives the clock CLKp; the other terminal of the capacitor C1a outputs the clock CLKp′. A terminal of the capacitor C1b receives the clock CLKn; the other terminal of the capacitor C1b outputs the clock CLKn′. The capacitor C1a and the capacitor C1b block the DC components of the clock CLKp and the clock CLKn. The DC component of the clock CLKp′ is dominated by the voltage at the node N4, and the DC component of the clock CLKn′ is dominated by the voltage at the node N5.

The DC voltage generation circuit 230p includes a resistor R4 and a resistor R5. The resistor R4 is coupled between the reference voltage VDD and a node N6. The resistor R5 is coupled between the node N6 and the reference voltage GND. That is to say, the DC voltage generation circuit 230p generates a DC voltage DCp through voltage division. The DC voltage DCp is coupled to the output port 202 (more specifically, the node N4) through the LPF circuit 250 (more specifically, through the resistor R2a).

The DC voltage generation circuit 230n includes a resistor R6 and a resistor R7. The resistor R6 is coupled between the reference voltage VDD and a node N7. The resistor R7 is coupled between the node N7 and the reference voltage GND. That is to say, the DC voltage generation circuit 230n generates the DC voltage DCn through voltage division.

The determination circuit 240 is coupled to the output port 202, the control voltage generation circuit 210, and the DC voltage generation circuit 230n and includes a logic circuit 242, an LPF circuit 244, a comparator 246, a switch SW1, and a switch SW2.

The logic circuit 242 is coupled to the output port 202 and generates the logic signal DA according to the output clock pair CLK′. More specifically, when the clock CLKp′ and the clock CLKn′ are both at a first level (e.g., high level or logic 1), the logic signal DA is at the first level. When at least one of the clock CLKp′ and the clock CLKn′ is at a second level (e.g., low level or logic 0), the logic signal DA is at the second level. People having ordinary skill in the art may implement the logic circuit 242 based on the above logic. In the embodiment of FIG. 2, the logic circuit 242 is embodied by an AND gate.

The LPF circuit 244 is coupled to the logic circuit 242 and includes a resistor R3 and a capacitor C3. The LPF circuit 244 generates a filtered logic signal DA′ by low-pass filtering the logic signal DA.

The comparator 246 is coupled to the LPF circuit 244 and configured to generate the control signal Enb by comparing the filtered logic signal DA′ with the reference voltage GND. More specifically, when the filtered logic signal DA′ is greater than the reference voltage GND, the control signal Enb is at the first level. When the filtered logic signal DA′ is not greater than the reference voltage GND, the control signal Enb is at the second level.

A terminal of the switch SW1 is coupled or electrically connected to the node N3; another terminal of the switch SW1 is coupled or electrically connected to a node N8 (which is further coupled to the output port 202 through the LPF circuit 250). A terminal of the switch SW2 is coupled or electrically connected to the node N7; another terminal of the switch SW2 is coupled or electrically connected to the node N8 (which is further coupled to the output port 202 through the LPF circuit 250). The switch SW1 is controlled by the control signal Enb, while the switch SW2 is controlled by the control signal #Enb. The control signal Enb and the control signal #Enb are inverted signals of each other. More specifically, when the control signal Enb is at the first level, the switch SW1 is turned on (so that the control voltage Vg is coupled to the output port 202) and the switch SW2 is turned off. When the control signal Enb is at the second level, the switch SW1 is turned off and the switch SW2 is turned on (so that the DC voltage DCn is coupled to the output port 202). In other words, the switch SW1 and the switch SW2 are not turned on at the same time.

In summary, the determination circuit 240 determines according to the clock CLKp′ and the clock CLKn′ whether to couple the control voltage Vg or the DC voltage DCn to the output port 202 (more specifically, the node N5).

The LPF circuit 250 is coupled to the output port 202 and configured to filter the output clock pair CLK′. In detail, the LPF circuit 250 includes the resistor R2a, a capacitor C2a, a resistor R2b, and a capacitor C2b. The resistor R2a and the capacitor C2a form a low-pass filter that is used to low-pass filter the clock CLKp′ to prevent the DC voltage DCp from jittering due to the toggling (transitioning from high level to low level, or from low level to high level) of the clock CLKp′. The resistor R2b and the capacitor C2b form another low-pass filter that is used to low-pass filter the clock CLKn′. In some embodiments, if the frequency of the clock CLKp′ and the clock CLKn′ is not high, then the LPF circuit 250 may be omitted.

In summary, when at least one of the clocks CLKp′ and CLKn′ is at the second level (state one), the clock adjustment circuit 200 adjusts the DC level of the clock CLKn′ to the DC voltage DCn. When the clock CLKp′ and the clock CLKn′ are both at the first level (state two), the clock adjustment circuit 200 adjusts the DC level of the clock CLKn′ to the control voltage Vg. Regardless of whether it is state one or state two, the clock adjustment circuit 200 adjusts the DC level of the clock CLKp′ to the DC voltage DCp. In other words, the clock adjustment circuit 200 sets the DC level of the clock CLKn′ to the DC voltage DCn or the control voltage Vg according to the clock CLKp′ and the clock CLKn′, and determines the magnitude of the control voltage Vg according to the reference resistor Rref and the transistor Mx.

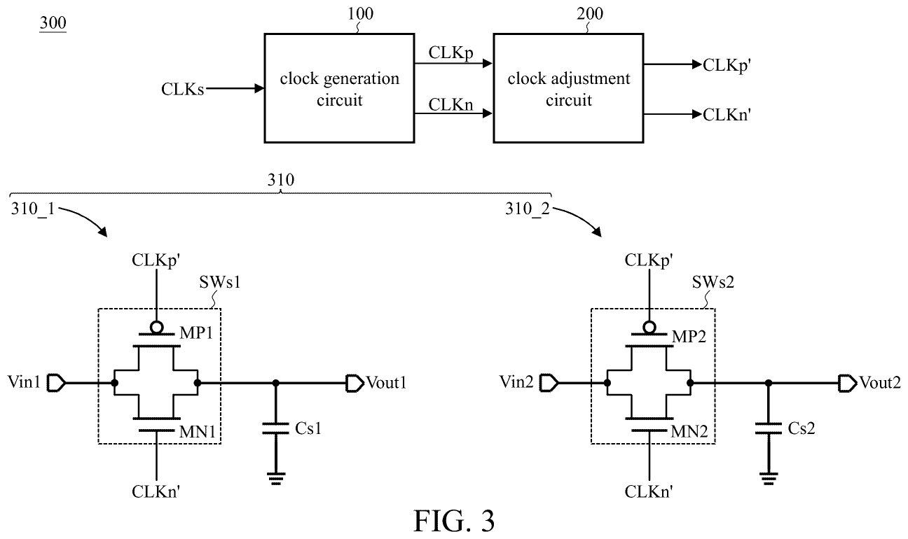

Reference is made to FIG. 3, which is the circuit diagram of the sampling device according to an embodiment of the present invention. A sampling device 300 includes the clock generation circuit 100, the clock adjustment circuit 200, and a sampling circuit 310. The sampling circuit 310 includes a sub-sampling circuit 310_1 and a sub-sampling circuit 310_2. The sub-sampling circuit 310_1 includes a switch SWs1 and a capacitor Cs1. The sub-sampling circuit 310_2 includes a switch SWs2 and a capacitor Cs2. The sub-sampling circuit 310_1 samples the input signal Vin1 to generate the output signal Vout1. The sub-sampling circuit 310_2 samples the input signal Vin2 to generate the output signal Vout2. The input signal Vin1 and the input signal Vin2 are a pair of input differential signals. The output signal Vout1 and the output signal Vout2 are a pair of output differential signals. The switch SWs1 is a transmission gate composed of a PMOS transistor MP1 and an NMOS transistor MN1. The switch SWs2 is a transmission gate composed of a PMOS transistor MP2 and an NMOS transistor MN2. The gates of the PMOS transistor MP1 and the PMOS transistor MP2 receive the clock CLKp′, while the gates of the NMOS transistor MN1 and the NMOS transistor MN2 receive the clock CLKn′.

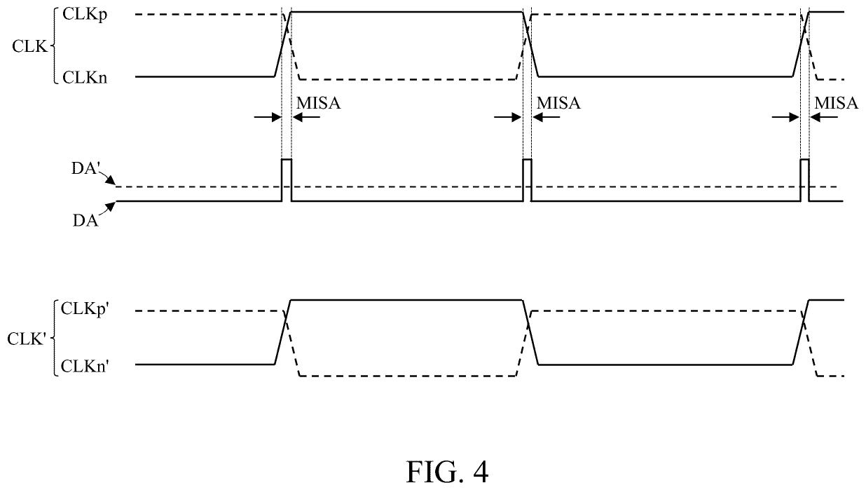

Reference is made to FIGS. 2 to 4. FIG. 4 is a schematic diagram of the waveforms of the clock CLKp, the clock CLKn, the logic signal DA, the filtered logic signal DA′, the clock CLKp′, and the clock CLKn′. As shown in FIG. 4, the rising and falling edges of the clock CLKp and the clock CLKn are not aligned (as indicated by the interval MISA in the figure, corresponding to the aforementioned state two). This causes the NMOS transistor MN1 or the NMOS transistor MN2 to remain conducting when the PMOS transistor MP1 or the PMOS transistor MP2 of the switch SWs1 or the switch SWs2 is turned off. Because the input signal Vin1 and the input signal Vin2 are a pair of differential signals (assuming Vin1=Vcm+dV, Vin2=Vcm−dV, where Vcm is the common-mode voltage), the gate-source voltage (Vgs) of the NMOS transistor MN1 of the switch SWs1 is less than the gate-source voltage (Vgs) of the NMOS transistor MN2 of the switch SWs2, resulting in the turn-on resistance (Ron_n1) of the NMOS transistor MN1 being greater than the turn-on resistance (Ron_n2) of the NMOS transistor MN2, which further leads to the sampling time constant τ1 (=Ron_n1×Cs1) of the sub-sampling circuit 310_1 being greater than the sampling time constant τ2 (=Ron_n2×Cs2) of the sub-sampling circuit 310_2 (when Cs1=Cs2). This results in the output signal Vout1 being more difficult to track the input signal Vin1, while the output signal Vout2 is easier to track the input signal Vin2, leading to a significant decrease in the linearity of the output signal (Vout1−Vout2) of the sampling circuit 310. Such a disadvantage becomes more significant as the frequency of the input signal and the sampling clock increases.

Continuing the previous paragraph, the turn-on resistance Ron_s1 of the switch SWs1 is Ron_p1//Ron_n1, while the turn-on resistance Ron_s2 of the switch SWs2 is Ron_p2//Ron_n2, wherein Ron_p1, Ron_n1, Ron_p2, and Ron_n2 are the turn-on resistances of the PMOS transistor MP1, the NMOS transistor MN1, the PMOS transistor MP2, and the NMOS transistor MN2, respectively. When the sampling circuit 310 is controlled by the input clock pair CLK shown in FIG. 4, the PMOS transistor MP1 is turned off earlier than the NMOS transistor MN1, and the PMOS transistor MP2 is turned off earlier than the NMOS transistor MN2. At this time, Ron_s1 is Ron_p1//Ron_n1≈Ron_n1 which is greater than Ron_s2 which is Ron_p2//Ron_n2≈Ron_n2. It can be observed that reducing the turn-on resistances Ron_n1 and Ron_n2 can decrease the sampling time constants τ1 and τ2, which helps to enhance the linearity of the sampling circuit 310.

Continuing with FIG. 2 to FIG. 4, the logic signal DA reflects the duration during which the clock CLKp and the clock CLKn are both at the first level (i.e., the interval MISA). When the filtered logic signal DA′ is greater than the reference voltage GND (indicating that the rising edges and the falling edges of the clock CLKp and the clock CLKn are not aligned), the determination circuit 240 couples the control voltage Vg to the output port 202 to adjust the DC level of the clock CLKn′ (changing from the DC voltage DCn to the control voltage Vg). Compared to the clock CLKn, the clock CLKn′ may reduce the turn-on resistance Ron_n1 of the NMOS transistor MN1 and the turn-on resistance Ron_n2 of the NMOS transistor MN2, improving the linearity of the sampling circuit 310. In other words, when the clock adjustment circuit 200 of the present invention is utilized in the sampling circuit, a reduction in linearity degradation caused by misaligned sampling clocks can be achieved.

Reference is made to FIG. 2. The turn-on resistance Ron_n1 of the NMOS transistor MN1 and the turn-on resistance Ron_n2 of the NMOS transistor MN2 may be set by adjusting the reference resistor Rref. More specifically, because the control voltage generation circuit 210 is a negative feedback circuit, when the control voltage generation circuit 210 settles, the turn-on resistance of the transistor Mx is substantially equal to the reference resistor Rref. Therefore, in some embodiments, the transistor Mx, the NMOS transistor MN1, and the NMOS transistor MN2 have substantially the same dimensions (i.e., aspect ratios), ensuring that the turn-on resistance Ron_n1 and the turn-on resistance Ron_n2 are substantially equal to the resistance value of the reference resistor Rref. In other words, the clock adjustment circuit 200 adjusts the clock CLKn according to the resistance value of the reference resistor Rref and the aspect ratio of the transistor Mx.

It should be noted that although the embodiment of FIG. 2 takes the adjustment of the clock CLKn′ as an example, people having ordinary skill in the art may modify the embodiment of FIG. 2 based on the above discussion to implement the adjustment to the clock CLKp′. In other embodiments, a clock adjustment circuit may also simultaneously implement adjustments to the clock CLKp′ and the clock CLKn′.

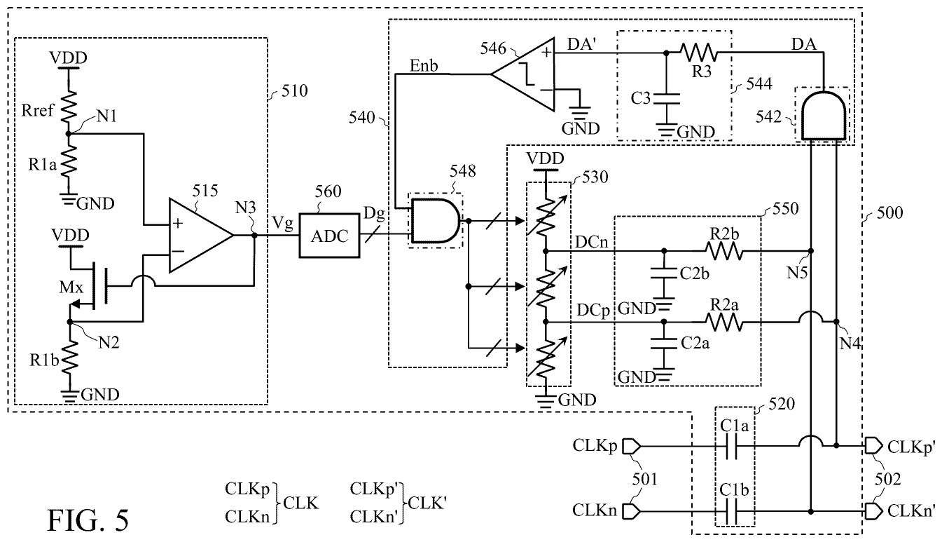

Reference is made to FIG. 5, which is the circuit diagram of the clock adjustment circuit according to another embodiment of the present invention. The clock adjustment circuit 500 is used to adjust the input clock pair CLK (inputted from the input port 501) to generate the output clock pair CLK′ (outputted from the output port 502). The clock adjustment circuit 500 includes a control voltage generation circuit 510, an AC coupling circuit 520, a DC voltage generation circuit 530, a determination circuit 540, an LPF circuit 550, and an analog-to-digital converter (ADC) 560 that are coupled to each other. The control voltage generation circuit 510, the amplifier 515, the AC coupling circuit 520, the logic circuit 542, the LPF circuit 544, the comparator 546, and the LPF circuit 550 have functions that are similar or identical to those of the control voltage generation circuit 210, the amplifier 215, the AC coupling circuit 220, the logic circuit 242, the LPF circuit 244, the comparator 246, and the LPF circuit 250 in FIG. 2, respectively; therefore, further elaboration is omitted for brevity.

The ADC 560 is coupled between the control voltage generation circuit 510 and the determination circuit 540 and configured to convert the control voltage Vg into the intermediate signal Dg. The logic circuit 548 of the determination circuit 540 determines whether to provide (couple) the intermediate signal Dg to the DC voltage generation circuit 530 according to the control signal Enb. More specifically, when the control signal Enb is at the first level, the output of the logic circuit 548 is equal to the intermediate signal Dg. When the control signal Enb is at the second level, the output of the logic circuit 548 is at the second level. People having ordinary skill in the art may implement the logic circuit 548 based on the logic discussed above. In the embodiment of FIG. 5, the logic circuit 548 is embodied by one or more AND gates.

The DC voltage generation circuit 530 is a voltage divider circuit. When the DC voltage generation circuit 530 is not controlled by the intermediate signal Dg, the DC voltage generation circuit 530 generates the preset DC voltage DCn and the preset DC voltage DCp. When the DC voltage generation circuit 530 is controlled by the intermediate signal Dg, the DC voltage generation circuit 530 adjusts at least one of the DC voltage DCn and the DC voltage DCp. For example, when the transistor Mx corresponds to the NMOS transistor MN1 and the NMOS transistor MN2 in FIG. 3, the DC voltage generation circuit 530 adjusts the DC voltage DCn according to the intermediate signal Dg. When the transistor Mx corresponds to the PMOS transistor MP1 and the PMOS transistor MP2 in FIG. 3, the DC voltage generation circuit 530 adjusts the DC voltage DCp according to the intermediate signal Dg. In short, the DC voltage generation circuit 530 may generate the DC voltage DCn and/or the DC voltage DCp according to the intermediate signal Dg.

The clock adjustment circuit 500 may be used to replace the clock adjustment circuit 200 in FIG. 3. Similarly, people having ordinary skill in the art may apply the adjustment mechanism of the present invention to the clock CLKn′ and the clock CLKp′ at the same time according to the embodiment of FIG. 5.

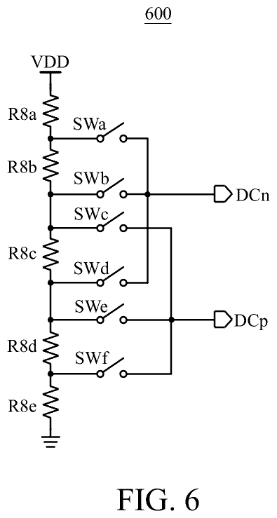

The DC voltage generation circuit 530 in FIG. 5 includes multiple series-connected variable resistors, and the resistance value of each variable resistor is controlled by the intermediate signal Dg. Reference is made to FIG. 6, which is the circuit diagram of the DC voltage generation circuit according to another embodiment of the present invention. The DC voltage generation circuit 530 in FIG. 5 may also be embodied by the DC voltage generation circuit 600. The DC voltage generation circuit 600 includes 5 resistors R8a to R8e and 6 switches SWa to SWf. The switches SWa to SWf are controlled by the intermediate signal Dg to adjust the DC voltage DCn and/or the DC voltage DCp.

The sampling circuits are intended to illustrate the invention by way of example and not to limit the scope of the claimed invention. People having ordinary skill in the art may apply the present invention to other circuits that utilize transmission gates as switches.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A clock adjustment circuit having an input port and an output port and configured to adjust an input clock pair to generate an output clock pair, the clock adjustment circuit comprising:
a control voltage generation circuit comprising a transistor and a reference resistor and configured to generate a control voltage according to the reference resistor, wherein the transistor is controlled by the control voltage;
an alternating current (AC) coupling circuit coupled between the input port and the output port;
a direct current (DC) voltage generation circuit configured to generate a DC voltage; and
a determination circuit coupled to the output port, the control voltage generation circuit, and the DC voltage generation circuit and configured to couple the control voltage or the DC voltage to the output port according to the output clock pair.

2. The clock adjustment circuit of claim 1, wherein the control voltage generation circuit further comprises:
an amplifier having a first input terminal, a second input terminal, and an output terminal, wherein the output terminal outputs the control voltage;
a first resistor coupled between the first input terminal and a first reference voltage; and
a second resistor coupled between the second input terminal and the first reference voltage;
wherein the reference resistor is coupled between a second reference voltage and the first input terminal, the transistor is coupled between the second reference voltage and the second input terminal, and a gate of the transistor is coupled to the output terminal.

3. The clock adjustment circuit of claim 2, wherein the AC coupling circuit comprises:
a first capacitor; and
a second capacitor;
one terminal of the first capacitor and one terminal of the second capacitor receive the input clock pair, and another terminal of the first capacitor and another terminal of the second capacitor output the output clock pair.

4. The clock adjustment circuit of claim 2 further comprising:
a low-pass filter (LPF) circuit coupled to the output port and configured to filter the output clock pair.

5. The clock adjustment circuit of claim 2, wherein the DC voltage generation circuit is a first DC voltage generation circuit, the DC voltage is a first DC voltage, and the clock adjustment circuit further comprises:
a second DC voltage generation circuit configured to generate a second DC voltage;
wherein the second DC voltage is coupled to the output port.

6. The clock adjustment circuit of claim 2, wherein the determination circuit comprises:
a logic circuit coupled to the output port and configured to generate a logic signal according to the output clock pair;
a low-pass filter (LPF) circuit coupled to the logic circuit and configured to filter the logic signal to generate a filtered logic signal;
a comparator coupled to the LPF circuit and configured to compare the filtered logic signal with the first reference voltage to generate a control signal;
a first switch coupled to the output port and the control voltage generation circuit and controlled by the control signal; and
a second switch coupled to the output port and the DC voltage generation circuit and controlled by the control signal;
wherein when the control signal is at a first level, the first switch is turned on to couple the control voltage to the output port; when the control signal is at a second level, the second switch is turned on to couple the DC voltage to the output port.

7. The clock adjustment circuit of claim 6, wherein the first switch and the second switch are not turned on simultaneously.

8. A clock adjustment circuit having an input port and an output port and configured to adjust an input clock pair to generate an output clock pair, the clock adjustment circuit comprising:
a control voltage generation circuit comprising a transistor and a reference resistor and configured to generate a control voltage according to the reference resistor, wherein the transistor is controlled by the control voltage;
an alternating current (AC) coupling circuit coupled between the input port and the output port;
an analog-to-digital converter (ADC) coupled to the control voltage generation circuit and configured to generate an intermediate signal according to the control voltage;
a direct current (DC) voltage generation circuit configured to generate a DC voltage according to the intermediate signal; and
a determination circuit coupled to the output port, the ADC, and the DC voltage generation circuit and configured to couple the intermediate signal to the DC voltage generation circuit according to the output clock pair.

9. The clock adjustment circuit of claim 8, wherein the control voltage generation circuit further comprises:
an amplifier having a first input terminal, a second input terminal, and an output terminal, wherein the output terminal outputs the control voltage;
a first resistor coupled between the first input terminal and a first reference voltage; and
a second resistor coupled between the second input terminal and the first reference voltage;
wherein the reference resistor is coupled between a second reference voltage and the first input terminal, the transistor is coupled between the second reference voltage and the second input terminal, and a gate of the transistor is coupled to the output terminal.

10. The clock adjustment circuit of claim 9, wherein the AC coupling circuit comprises:
a first capacitor; and
a second capacitor;
one terminal of the first capacitor and one terminal of the second capacitor receive the input clock pair, and another terminal of the first capacitor and another terminal of the second capacitor output the output clock pair.

11. The clock adjustment circuit of claim 9 further comprising:
a low-pass filter (LPF) circuit coupled to the output port and configured to filter the output clock pair.

12. The clock adjustment circuit of claim 9, wherein the determination circuit comprises:
a first logic circuit coupled to the output port and configured to generate a logic signal according to the output clock pair;
a low-pass filter (LPF) circuit coupled to the first logic circuit and configured to filter the logic signal to generate a filtered logic signal;
a comparator coupled to the LPF circuit and configured to compare the filtered logic signal with the first reference voltage to generate a control signal; and
a second logic circuit coupled to the comparator and configured to determine whether to couple the intermediate signal to the DC voltage generation circuit according to the control signal.

13. A sampling device comprising:
a clock generation circuit configured to generate a first clock and a second clock according to a reference clock;
a clock adjustment circuit coupled to the clock generation circuit and configured to adjust the first clock and the second clock to generate a third clock and a fourth clock; and
a sampling circuit coupled to the clock adjustment circuit and configured to sample an input signal according to the third clock and the fourth clock to generate an output signal;
wherein the sampling circuit comprises a transmission gate, the transmission gate comprises a P-channel metal-oxide-semiconductor field-effect transistor and an N-channel metal-oxide-semiconductor field-effect transistor, the P-channel metal-oxide-semiconductor field-effect transistor and the N-channel metal-oxide-semiconductor field-effect transistor respectively receive the third clock and the fourth clock;
wherein the clock adjustment circuit comprises a negative feedback circuit, the negative feedback circuit comprises a reference resistor and a transistor, and the clock adjustment circuit adjusts the first clock or the second clock according to a resistance value of the reference resistor and an aspect ratio of the transistor;
wherein the transistor has a substantially identical aspect ratio to the P-channel metal-oxide-semiconductor field-effect transistor or the N-channel metal-oxide-semiconductor field-effect transistor.

14. The sampling device of claim 13, wherein the transmission gate is a first transmission gate, the P-channel metal-oxide-semiconductor field-effect transistor is a first P-channel metal-oxide-semiconductor field-effect transistor, the N-channel metal-oxide-semiconductor field-effect transistor is a first N-channel metal-oxide-semiconductor field-effect transistor, the sampling circuit further comprises a second transmission gate, the second transmission gate comprises a second P-channel metal-oxide-semiconductor field-effect transistor and a second N-channel metal-oxide-semiconductor field-effect transistor, the second P-channel metal-oxide-semiconductor field-effect transistor and the second N-channel metal-oxide-semiconductor field-effect transistor respectively receive the third clock and the fourth clock, and the input signal is a differential signal.

15. The sampling device of claim 13, wherein the clock adjustment circuit has an input port and an output port, and the negative feedback circuit generates, according to the reference resistor, a control voltage used to control the transistor, the clock adjustment circuit further comprises:
an alternating current (AC) coupling circuit coupled between the input port and the output port;
a direct current (DC) voltage generation circuit configured to generate a DC voltage; and
a determination circuit coupled to the output port, the negative feedback circuit, and the DC voltage generation circuit and configured to couple the control voltage or the DC voltage to the output port according to the third clock and the fourth clock.

16. The sampling device of claim 15, wherein the negative feedback circuit further comprises:
an amplifier having a first input terminal, a second input terminal, and an output terminal, wherein the output terminal outputs the control voltage;
a first resistor coupled between the first input terminal and a first reference voltage; and
a second resistor coupled between the second input terminal and the first reference voltage;
wherein the reference resistor is coupled between a second reference voltage and the first input terminal, the transistor is coupled between the second reference voltage and the second input terminal, and a gate of the transistor is coupled to the output terminal.

17. The sampling device of claim 15, wherein the determination circuit comprises:
a logic circuit coupled to the output port and configured to generate a logic signal according to the third clock and the fourth clock;
a low-pass filter (LPF) circuit coupled to the logic circuit and configured to filter the logic signal to generate a filtered logic signal;
a comparator coupled to the LPF circuit to compare the filtered logic signal with a reference voltage to generate a control signal;
a first switch coupled to the output port and the negative feedback circuit and controlled by the control signal; and
a second switch coupled to the output port and the DC voltage generation circuit and controlled by the control signal;
wherein when the control signal is at a first level, the first switch is turned on to couple the control voltage to the output port; when the control signal is at a second level, the second switch is turned on to couple the DC voltage to the output port.

18. The sampling device of claim 13, wherein the clock adjustment circuit has an input port and an output port, and the negative feedback circuit generates, according to the reference resistor, a control voltage used to control the transistor, the clock adjustment circuit further comprises:
an alternating current (AC) coupling circuit coupled between the input port and the output port;
an analog-to-digital converter (ADC) coupled to the negative feedback circuit and configured to generate an intermediate signal according to the control voltage;
a direct current (DC) voltage generation circuit configured to generate a DC voltage according to the intermediate signal; and
a determination circuit coupled to the output port, the ADC, and the DC voltage generation circuit and configured to couple the intermediate signal to the DC voltage generation circuit according to the third clock and the fourth clock.

19. The sampling device of claim 18, wherein the negative feedback circuit further comprises:
an amplifier having a first input terminal, a second input terminal, and an output terminal, wherein the output terminal outputs the control voltage;
a first resistor coupled between the first input terminal and a first reference voltage; and
a second resistor coupled between the second input terminal and the first reference voltage;
wherein the reference resistor is coupled between a second reference voltage and the first input terminal, the transistor is coupled between the second reference voltage and the second input terminal, and a gate of the transistor is coupled to the output terminal.

20. The sampling device of claim 18, wherein the determination circuit comprises:
a first logic circuit coupled to the output port and configured to generate a logic signal according to the third clock and the fourth clock;
a low-pass filter (LPF) circuit coupled to the first logic circuit and configured to filter the logic signal to generate a filtered logic signal;
a comparator coupled to the LPF circuit to compare the filtered logic signal with a reference voltage to generate a control signal; and
a second logic circuit coupled to the comparator and configured to determine whether to couple the intermediate signal to the DC voltage generation circuit according to the control signal.
